(19) United States
(12) Patent Application Publication
(10) Pub. No.: US 2016/0071741 A1
(43) Pub. Date: Mar. 10, 2016

(54) METHOD FOR MANUFACTURING SEMICONDUCTOR DEVICE

(71) Applicant: KABUSHIKI KAISHA TOSHIBA, Tokyo (JP)

(72) Inventors: Tsubasa IMAMURA, Kuwana (JP); Mitsuhiro OMURA, Kuwana (JP)

(21) Appl. No.: 14/642,948

(22) Filed: Mar. 10, 2015

(30) Foreign Application Priority Data
Sep. 9, 2014 (JP) 2014-183633

(51) Int. Cl. H01L 21/311; H01L 27/115; H01L 21/02

(52) U.S. Cl. CPC H01L 21/31144; H01L 21/31116; H01L 21/0217; H01L 21/02164; H01L 21/02118; H01L 27/11556; H01L 27/11582

(57) ABSTRACT

According to one embodiment, a method for manufacturing a semiconductor device includes forming a mask layer made of a material different from a material of an etching target layer above the etching target layer. The method includes forming a plurality of first mask holes, sacrificial films being buried in the first mask holes, and a plurality of second mask holes, in the mask layer. The method includes retreating the sacrificial films in a depth direction of the first mask holes to expose portions of the first mask holes onto the sacrificial films. The method includes etching the etching target layer under the second mask holes using the mask layer and the sacrificial films as a mask, to form holes in the etching target layer under the second mask holes.

### CROSS-REFERENCE TO RELATED APPLICATION

This application is based upon and claims the benefit of priority from Japanese Patent Application No. 2014-183633, filed on Sep. 9, 2014; the entire contents of which are incorporated herein by reference.

### FIELD

Embodiments described herein relate generally to a method for manufacturing a semiconductor device.

### BACKGROUND

A memory device with a three-dimensional structure has been proposed. In the memory device, a memory hole is formed in a stacked body including a plurality of electrode layers functioning as control gates in memory cells via insulating layers. A silicon body serving as a channel is provided on a sidewall of the memory hole via a charge storage film.

In such a memory cell array with the three-dimensional structure, when the number of electrode layers to be stacked increases according to an increase in the storage capacity, and thus an aspect ratio of the memory hole increases, it tends to be hard to form the hole with high circularity in a uniform diameter in the stacking direction.

### BRIEF DESCRIPTION OF THE DRAWINGS

FIG. 1 is a schematic perspective view of a semiconductor device of an embodiment;

FIG. 2 is an enlarged schematic cross-sectional view of a part of the semiconductor device of the embodiment;

FIGS. 3 to 28 are schematic views showing a method for manufacturing the semiconductor device of the embodiment;

FIG. 29 is a schematic cross-sectional view showing asymmetric erosion in a mask layer; and

FIGS. 30A to 36B are schematic views showing a method for manufacturing the semiconductor device of the embodiment.

### DETAILED DESCRIPTION

According to one embodiment, a method for manufacturing a semiconductor device includes forming a mask layer made of a material different from a material of an etching target layer above the etching target layer. The method includes forming a plurality of first mask holes, a plurality of sacrificial films, and a plurality of second mask holes in the mask layer. The sacrificial films are buried in the first mask holes and made of a material different from a material of the mask layer. The method includes retreating the sacrificial films in a depth direction of the first mask holes to expose portions of the first mask holes onto the sacrificial films. The method includes etching the etching target layer under the second mask holes using the mask layer and the sacrificial films as a mask, to form holes in the etching target layer under the second mask holes.

Hereinafter, with reference to the drawings, an embodiment will be described. In the drawings, the same constituent elements are given the same reference numerals.

In the embodiment, for example, a semiconductor memory device having a memory cell array with a three-dimensional structure will be described as a semiconductor device.

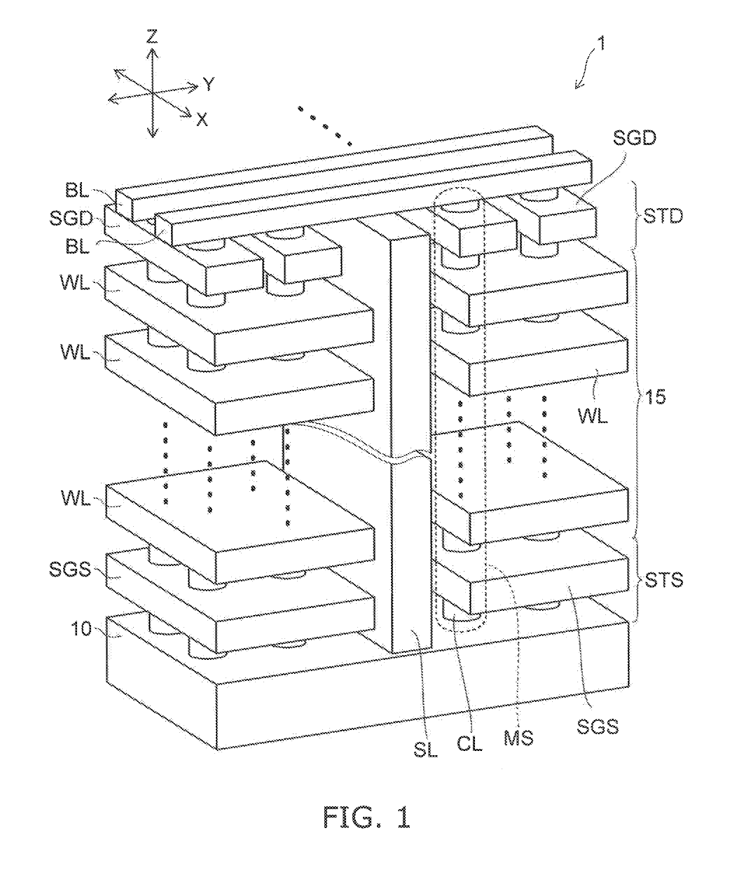

FIG. 1 is a schematic perspective view of a memory cell array 1 of the embodiment. In FIG. 1, for better understanding, an insulating layer is not shown.

In FIG. 1, two directions which are parallel to a major surface of a substrate 10 and are perpendicular to each other are set as an X-direction (first direction) and a Y-direction (second direction), and a direction perpendicular to both of the X-direction and the Y-direction is set as a Z-direction (a third direction or a stacking direction).

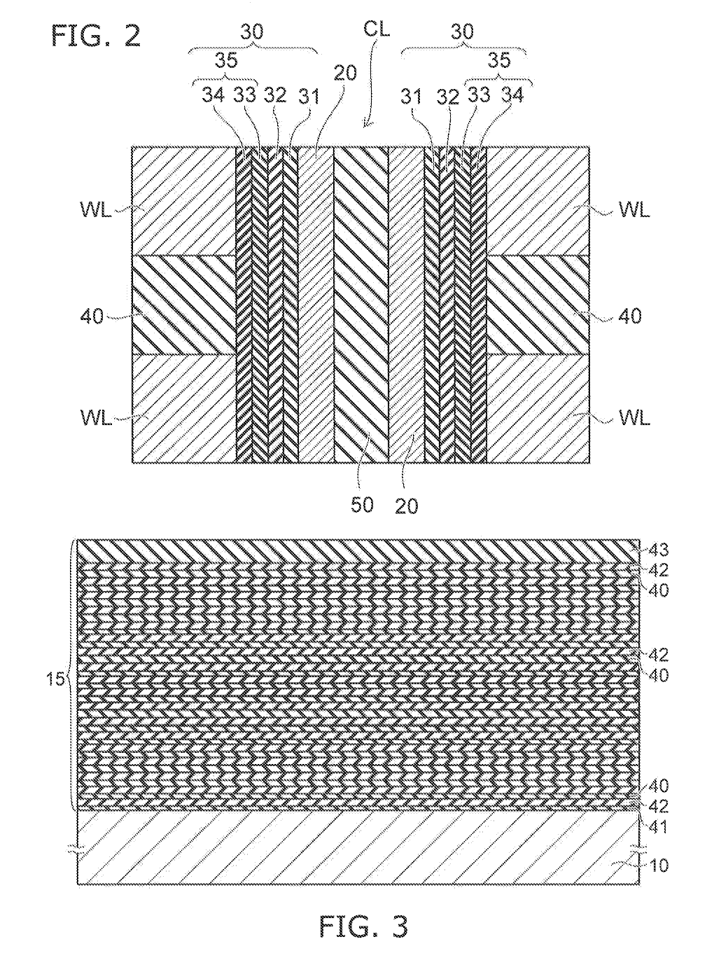

Source side select gates (lower gate layers) SGS are provided on the substrate 10 via the insulating layer. A stacked body 15 including a plurality of electrode layers WL and a plurality of insulating layers 40 (refer to FIG. 2) is provided on the source side select gates SGS. The electrode layers WL and the insulating layers 40 are alternately stacked. Drain side select gates (upper gate layers) SGD are provided on the uppermost electrode layers WL via the insulating layer.

The source side select gates SGS, the drain side select gates SGD, and the electrode layers WL are metal layers (for example, layers mainly containing tungsten). Alternatively, the source side select gates SGS, the drain side select gates SGD, and the electrode layers WL are, for example, silicon layers which contain silicon as a main component, and boron is doped in the silicon layers as an impurity for giving conductivity thereto. Alternatively, the source side select gates SGS, the drain side select gates SGD, and the electrode layers WL may contain metal silicide.

A plurality of bit lines BL (metal films) are provided on the drain side select gates SGD via an insulating layer (not shown). The drain side select gates SGD extend in the X-direction, and the bit lines BL extend in the Y-direction.

A plurality of columnar parts CL penetrate through the stacked body 15. The columnar parts CL extend in the stacking direction (Z-direction) of the stacked body 15. The columnar parts CL are formed, for example, in a columnar shape or an elliptic columnar shape.

The stacked body 15, the source side select gates SGS, and the drain side select gates SGD are isolated into a plurality of parts in the Y-direction. For example, source layers SL are provided at the isolation parts.

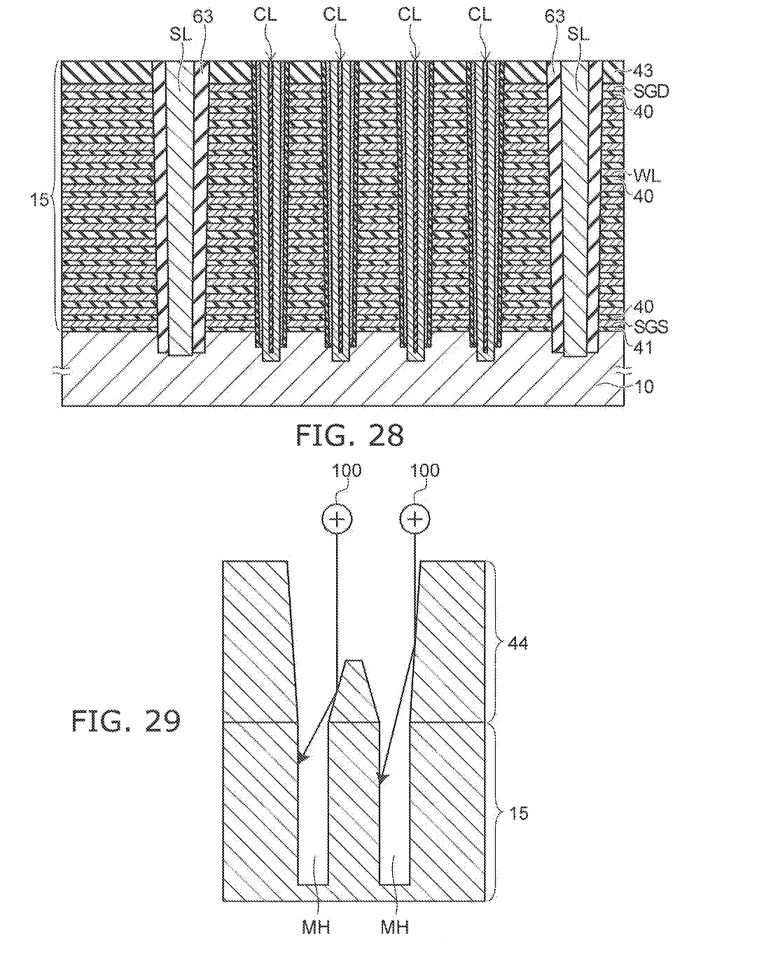

The source layers SL contain a metal (for example, tungsten). A lower end of each of the source layers SL is connected to the substrate 10. An upper end of the source layer SL is connected to an upper layer interconnection (not shown). An insulating film 63 shown in FIG. 28 is provided between the source layer SL and the electrode layers WL, between the source layer SL and the source side select gate SGS, and between the source layer SL and the drain side select gate SGD.

FIG. 2 is an enlarged schematic cross-sectional view of a portion of the columnar part CL.

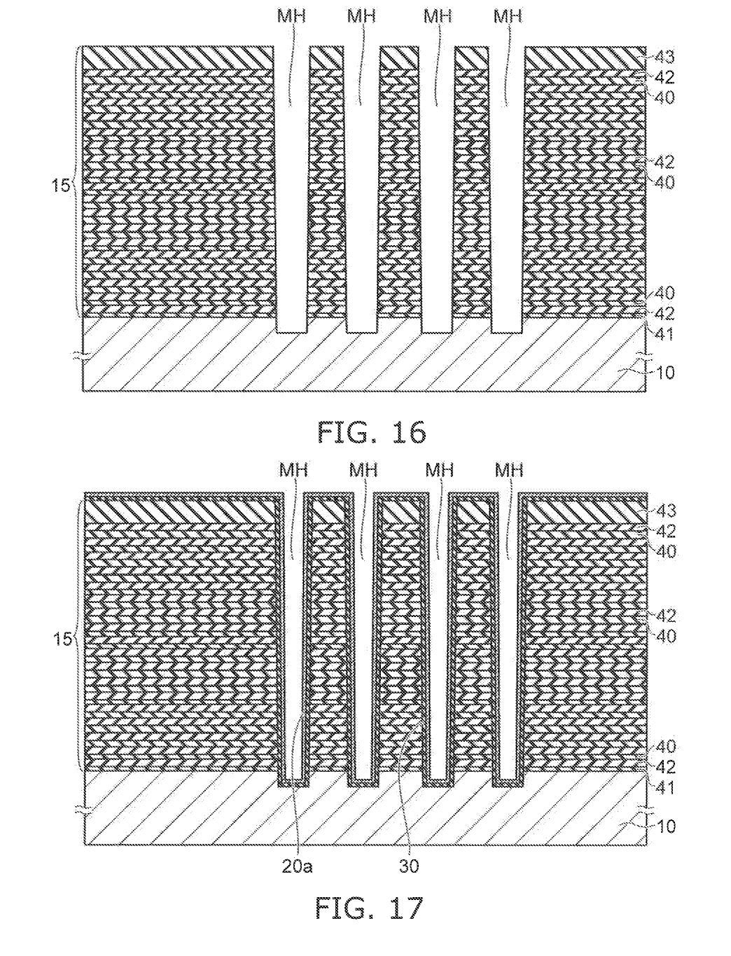

The columnar part CL is formed inside a memory hole MH (refer to FIG. 16) formed in the stacked body 15. A channel body (semiconductor body) 20 as a semiconductor channel is provided in the memory hole MH. The channel body 20 is, for example, a silicon film which has silicon as a main component. The channel body 20 does not substantially contain impurities.

Each of the channel bodies 20 is formed in a tubular shape which extends in the stacking direction of the stacked body 15. Upper ends of the channel bodies 20 penetrate through the drain side select gates SGD and are connected to the bit lines BL shown in FIG. 1.

Lower ends of the channel bodies 20 penetrate through the source side select gates SGS and are connected to the substrate 10. The lower ends of the channel bodies 20 are electrically connected to the source layer SL via the substrate 10.

As shown in FIG. 2, a memory film 30 is provided between a sidewall of the memory hole and the channel body 20. The memory film 30 has a block insulating film 35, a charge storage film 32, and a tunnel insulating film 31. The memory film 30 is formed in a tubular shape which extends in the stacking direction of the stacked body 15.

The block insulating film 35, the charge storage film 32, and the tunnel insulating film 31 are provided in this order from the electrode layer WL side between the electrode layer WL and the channel body 20. The block insulating film 35 is in contact with the electrode layers WL, the tunnel insulating film 31 is in contact with the channel body 20, and the charge storage film 32 is provided between the block insulating film 35 and the tunnel insulating film 31.

The memory film 30 surrounds an outer circumferential surface of the channel body 20. The electrode layers WL surround the outer circumferential surface of the channel body 20 via the memory films 30. A core insulating film 50 is provided inside the channel body 20.

The electrode layers WL function as control gates of the memory cells. The charge storage film 32 functions as a data memory layer which stores electric charge injected from the channel body 20. The memory cell with a vertical transistor structure is formed in which the control gate surrounds the channel at an intersection between the channel body 20 and each of the electrode layers WL.

The semiconductor memory device of the embodiment is a nonvolatile semiconductor memory device which enables data to be electrically erasable and programmable and can hold stored content even if power is turned off.

The memory cell is, for example, a charge trap type memory cell. The charge storage film 32 has a plurality of trap sites for trapping electric charge, and includes, for example, a silicon nitride film.

The tunnel insulating film 31 serves as a potential barrier when electric charge is injected into the charge storage film 32 from the channel body 20 or when electric charge stored in the charge storage film 32 is diffused to the channel body 20. The tunnel insulating film 31 includes, for example, a silicon oxide film. As the tunnel insulating film 31, a laminate film (an ONO film) which is formed of a pair of silicon oxide films and a silicon nitride film interposed therebetween may be used. If the ONO film is used as the tunnel insulating film 31, an erasure operation can be performed in a low electric field when compared with a single layer of a silicon oxide film.

The block insulating film 35 prevents electric charge stored in the charge storage film 32 from being diffused to the electrode layers WL. The block insulating film 35 has a cap film 34 which is provided to be in contact with the electrode layers WL and a block film 33 which is provided between the cap film 34 and the charge storage film 32.

The block film 33 is, for example, a silicon oxide film. The cap film 34 is a film having a higher dielectric constant than that of the silicon oxide film, and is, for example, a silicon nitride film, an aluminum oxide film, a hafnium oxide film, or an yttrium oxide film. The cap film 34 is provided to be in contact with the electrode layers WL, and thus it is possible to minimize back tunneling of electrons which are injected from the electrode layers WL during an erasure operation.

As shown in FIG. 1, a drain side select transistor STD is provided at the upper ends of the columnar parts CL, and a source side select transistor STS is provided at the lower ends of the columnar parts CL.

The memory cell, the drain side select transistor STD, and the source side select transistor STS are vertical transistors in which a current flows in the stacking direction (Z-direction) of the stacked body 15.

The drain side select gate SGD functions as a gate electrode (control gate) of the drain side select transistor STD. An insulating film (not shown) which functions as a gate insulating film of the drain side select transistor STD is provided between the drain side select gate SGD and the channel body 20.

The source side select gate SGS functions as a gate electrode (control gate) of the source side select transistor STS. An insulating film (not shown) which functions as a gate insulating film of the source side select transistor STS is provided between the source side select gate SGS and the channel body 20.

A plurality of memory cells having the electrode layers WL of the respective layers as control gates are provided between the drain side select transistor STD and the source side select transistor STS. The plurality of memory cells, the drain side select transistor STD, and the source side select transistor STS are connected in series to each other via the channel body 20 so as to constitute a single memory string MS. A plurality of memory strings MS are arranged in the X-direction and the Y-direction, and thus the plurality of memory cells are provided in a three-dimensional manner in the X-direction, the Y-direction, and the Z-direction.

The memory hole in which the columnar parts CL are formed is formed by using, for example, a reactive ion etching (RIE) method in which a mask layer formed on the stacked body is used. In order to increase the storage capacity, it is desirable to form the memory cells with high density. For example, there is a tendency for a diameter of the memory hole to further decrease and for the number of stacked electrode layers WL to increase, and thus the memory holes become fine holes with a considerably high aspect ratio.

Holes (mask holes) are also formed in the mask layer by using the RIE method. If an aspect ratio of the memory holes increases, a thickness of the mask layer also increases, and thus an aspect ratio of the mask holes tends to increase as well. In RIE on the holes with a high aspect ratio, if the symmetry of arrangement patterns of the plurality of holes is low, the mask layer is asymmetrically eroded during the RIE, and thus it tends to be hard to form holes with high circularity and uniform sizes.

FIG. 29 is a schematic cross-sectional view showing asymmetric erosion in the mask layer.

For example, a mask layer 44 of a region in which a distance between holes is relatively short tends to retreat in a thickness direction relatively fast as shown in FIG. 29. If such asymmetric mask erosion occurs, a side surface of the mask hole tends to be tapered. If ions 100 are recoiled on the tapered surface in a tilt direction, this leads to side etching of the memory hole MH, and thus there is a possibility that a shape of the memory hole MH may deteriorate.

Therefore, according to the embodiment described below, there is provided a method of forming a memory hole, capable of minimizing asymmetric erosion in a mask layer, and, as a result, of appropriately controlling a shape of a memory hole.

Hereinafter, with reference to FIGS. 3 to 28, a description will be made of a method of forming a memory hole of the semiconductor memory device of the embodiment.

FIGS. 3 and 14 to 28 are schematic cross-sectional views showing a method for manufacturing the semiconductor memory device of the embodiment.

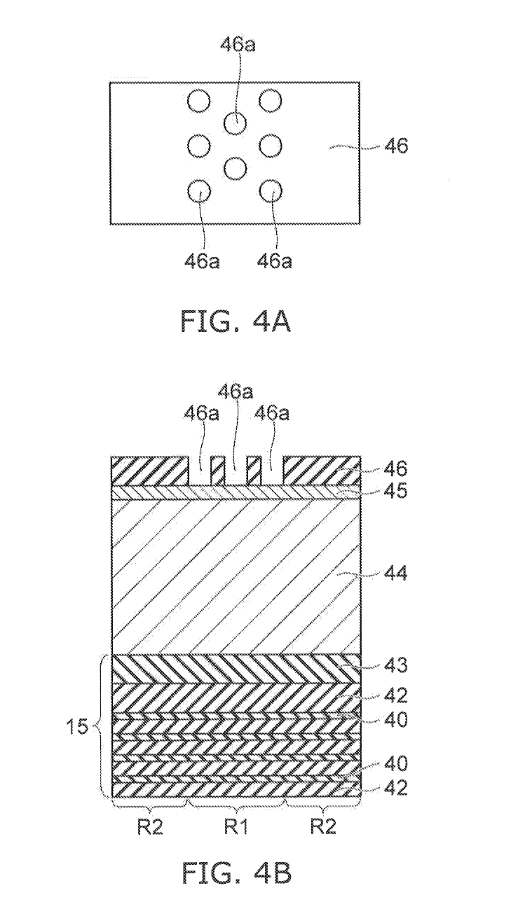

FIGS. 4B, 5B, 6B, 7B, 8B, 9B, 10B, 11B, 12B and 13B are cross-sectional views thereof.

FIGS. 4A, 5A, 6A, 7A, 8A, 9A, 10A, 11A, 12A and 13A respectively correspond to top views of FIGS. 4B, 5B, 6B, 7B, 8B, 9B, 10B, 11B, 12B and 13B.

As shown in FIG. 3, an etching target layer (base layer) 15 is formed on the substrate 10 via an insulating layer 41. The etching target layer 15 is a stacked body which has a plurality of sacrificial layers (first layers) 42 and a plurality of insulating layers (second layers) 40. The substrate 10 is, for example, a semiconductor substrate, and is a silicon substrate.

The insulating layer 41 is formed on the substrate 10. The sacrificial layers 42 and the insulating layers 40 are alternately formed on the insulating layer 41. A process of alternately forming the sacrificial layers 42 and the insulating layers 40 is repeatedly performed multiple times. The insulating layer 40 is provided between the sacrificial layers 42. The number of stacked sacrificial layers 42 and insulating layers 40 is not limited to the shown number of layers.

The insulating layers 40 are, for example, silicon oxide films. The sacrificial layers 42 are films made of a material different from that of the insulating layers 40, and are, for example, silicon nitride films. The sacrificial layers 42 are replaced with the electrode layers WL in the subsequent processes. The sacrificial layers 42 and the insulating layers 40 are formed by using, for example, a chemical vapor deposition (CVD) method.

An insulating layer 43 is formed on the uppermost sacrificial layer 42. As shown in FIG. 4B, a mask layer 44 is formed on the etching target layer 15. The mask layer 44 is a carbon film formed by using, for example, a CVD method. The mask layer 44 may be a tungsten film which is formed by using, for example, a sputtering method.

An intermediate film 45 is formed on the mask layer 44, and a resist film 46 is formed on the intermediate film 45. The intermediate film 45 is made of a material different from that of the mask layer 44 and the resist film 46, and is, for example, a spin on glass (SOG) film containing silicon oxide.

A plurality of first openings (holes) 46a are formed in the resist film 46 by using a lithography method. The first openings 46a reach the intermediate film 45.

The etching target layer 15 has a first region R1 and a second region R2. The second region R2 is a region where the memory hole MH is possible to be formed.

The first openings 46a are formed in a region on the first region R1. As shown in FIG. 4A, the plurality of first openings 46a are formed in a hexagonal close-packed pattern, for example.

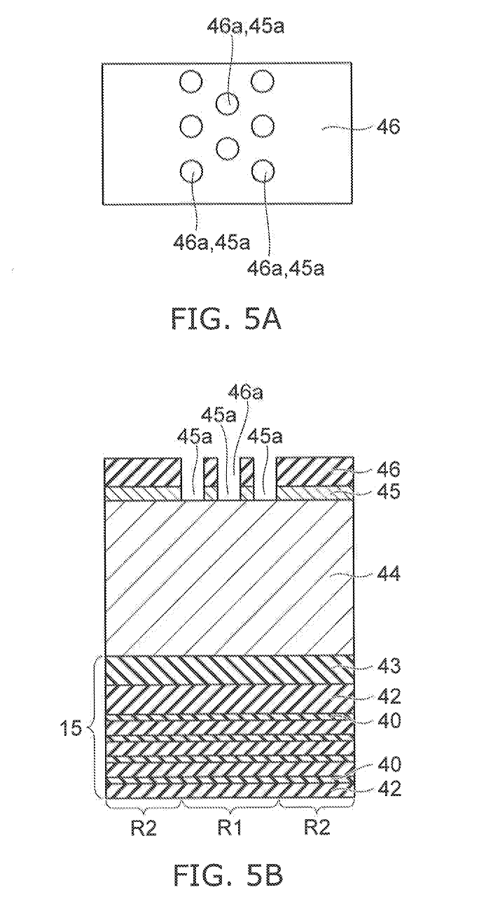

As shown in FIG. 5B, first openings (holes) 45a are formed in the intermediate film 45 according to an RIE method of using the resist film 46 as a mask. The first openings 45a reach the mask layer 44.

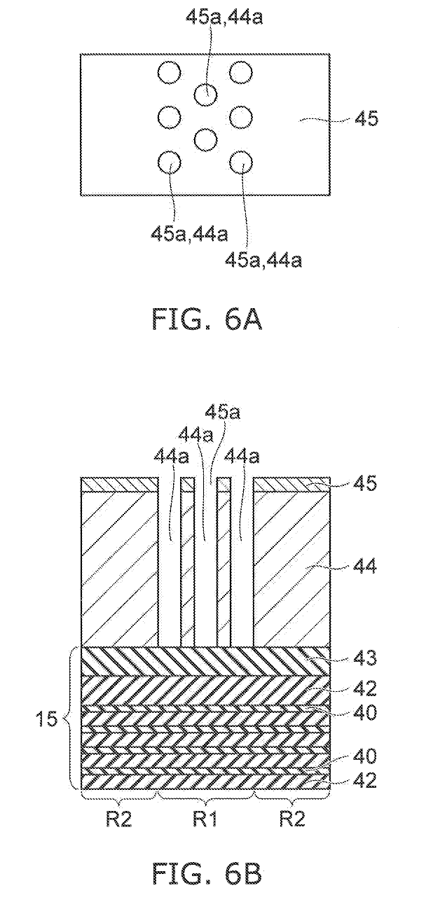

In addition, as shown in FIG. 6B, first mask holes 44a are formed in the mask layer 44 according to an RIE method of using the resist film 46 and the intermediate film 45 as a mask. The resist film 46 disappears during the etching.

The first mask holes 44a penetrate through the mask layer 44, and reach the uppermost layer (the insulating layer 43) of the etching target layer 15.

The first mask holes 44a are formed in a region on the first region R1. As shown in FIG. 6A, the plurality of first mask holes 44a are formed in a hexagonal close-packed pattern, for example.

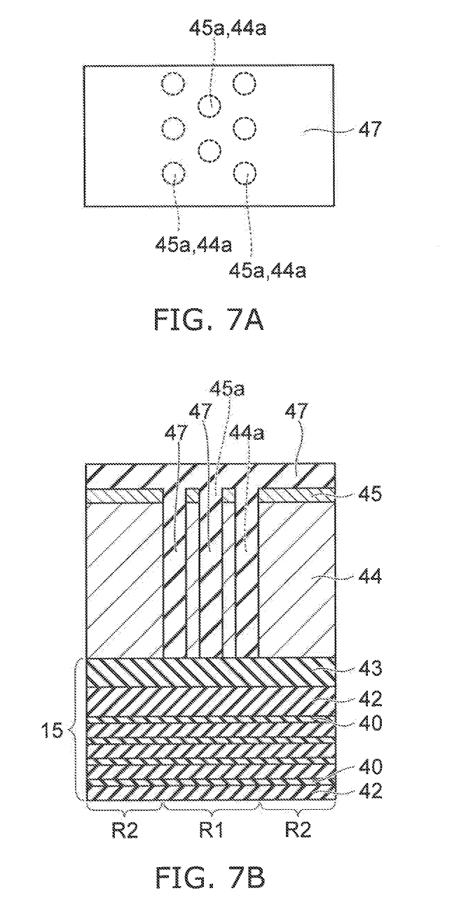

As shown in FIG. 7B, a sacrificial film 47 is buried in the first mask holes 44a. The sacrificial film 47 is formed in a columnar shape surrounded by the mask layer 44.

The sacrificial film 47 is made of a material different from that of the mask layer 44. In addition, the sacrificial film 47 has an etching resistance lower than that of the mask layer 44 relative to an etching condition of the etching target layer 15. In other words, when the etching target layer 15 is etched, an etching rate (second rate) of the sacrificial film 47 is higher than an etching rate (first rate) of the mask layer 44.

As the sacrificial film 47, for example, an organic film is buried in the first mask holes 44a by using a coating method. Alternatively, as the sacrificial film 47, a film containing silicon oxide is buried in the first mask holes 44a by using a coating method. The sacrificial film 47 is supplied into the first openings 45a of the intermediate film 45 and also on the intermediate film 45.

The sacrificial film 47 on the intermediate film 45, the intermediate film 45, and the sacrificial film 47 in the first openings 45a are removed. An upper surface of the mask layer 44 and an upper surface of the sacrificial film 47 in the first mask holes 44a are planarized.

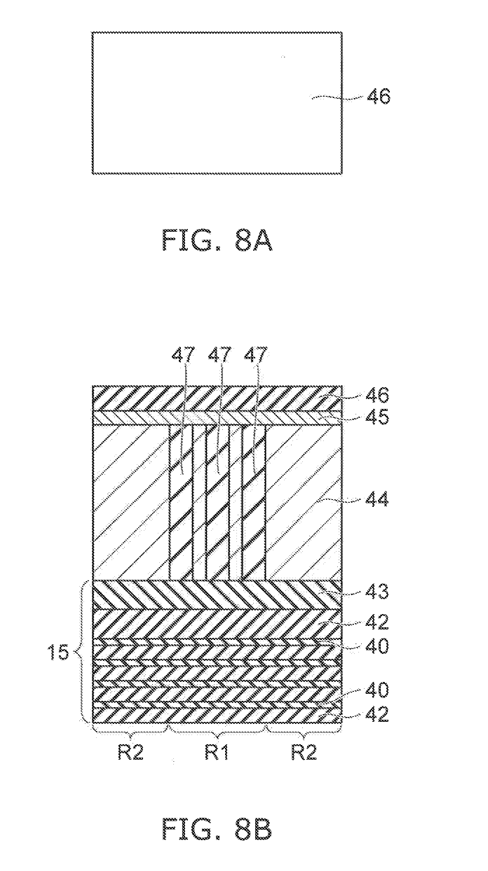

As shown in FIG. 8B, the intermediate film 45 is formed on the planarized surface again, and the resist film 46 is formed on the intermediate film 45.

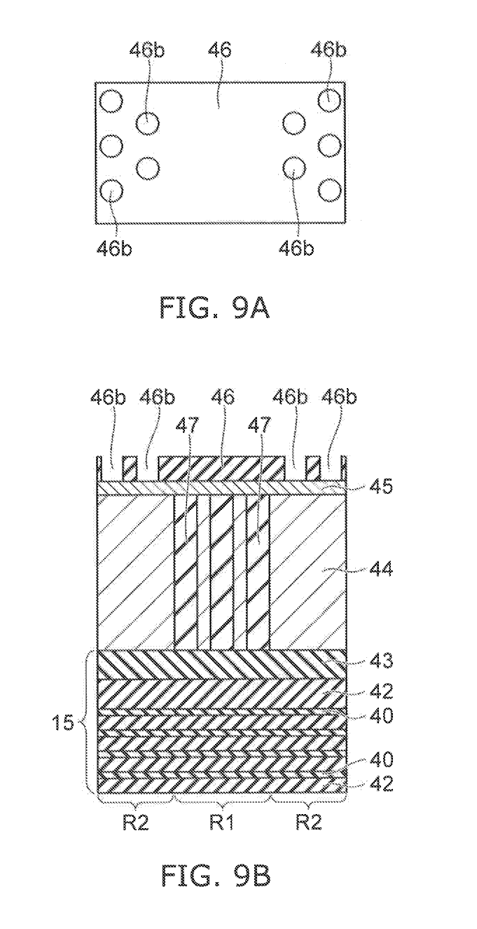

As shown in FIG. 9B, a plurality of second openings (holes) 46b are formed in the resist film 46 by using a lithography method. The second openings 46b reach the intermediate film 45.

The second openings 46b are formed in a region on the second region R2. As shown in FIG. 9A, the plurality of second openings 46b are formed in a hexagonal close-packed pattern, for example. The second openings 46b are not formed in the region on the first region R1, and the sacrificial film 47 is protected by the resist film 46 via the intermediate film 45.

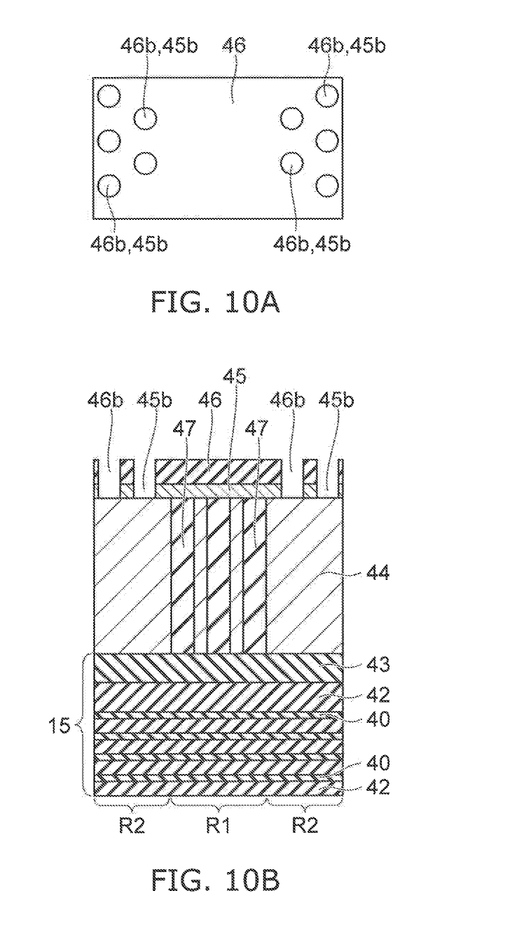

As shown in FIG. 10B, second openings (holes) 45b are formed in the intermediate film 45 according to an RIE method using the resist film 46 having the second openings 46b as a mask. The second openings 45b reach the mask layer 44.

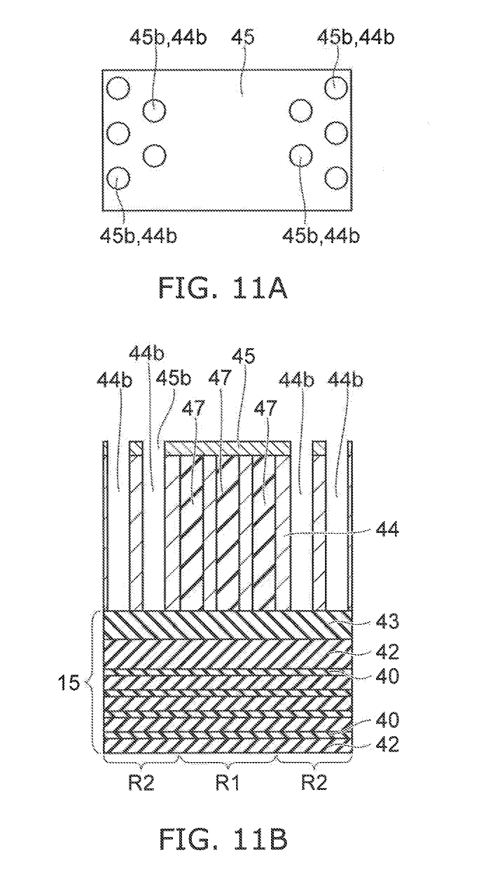

In addition, as shown in FIG. 11B, second mask holes 44b are formed in the mask layer 44 according to an RIE method using the resist film 46 and the intermediate film 45 as a mask. During the etching, the resist film 46 disappears.

The second mask holes 44b penetrate through the mask layer 44, and reach the uppermost layer (the insulating layer 43) of the etching target layer 15. The second mask holes 44b are formed in the region on the second region R2. As shown in FIG. 11A, the plurality of second mask holes 44b are formed in a hexagonal close-packed pattern, for example.

During etching for forming the second mask holes 44b, the intermediate film 45 is left on the sacrificial film 47, and thus the sacrificial film 47 is protected by the intermediate film 45 so as not to be etched.

The insulating layer 43 which is a base film of the mask layer 44, is made of a material different from that of the mask layer 44. The insulating layer 43 is, for example, a silicon oxide layer, and functions as an etching stopper during etching for forming the second mask holes 44b.

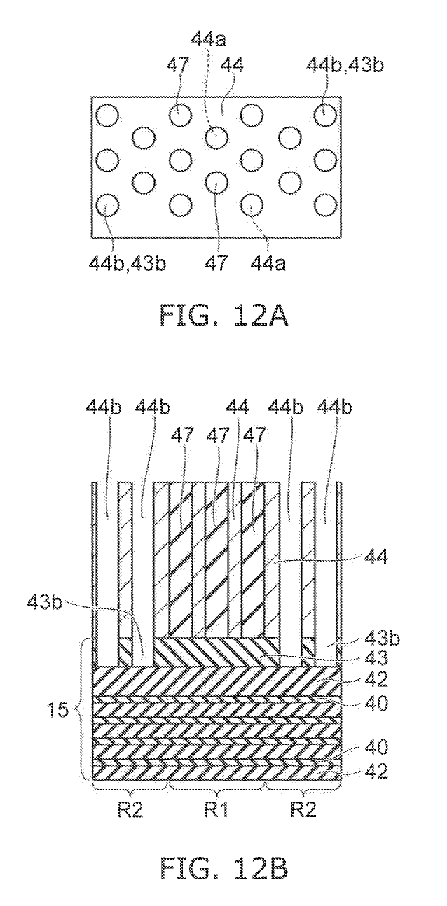

Subsequently, openings (holes) 43b shown in FIG. 12B are formed in the insulating layer 43 according to an RIE method of using the remaining intermediate film 45 as a mask. The openings 43b are formed under the second mask holes 44b and reach the uppermost sacrificial layer 42.

At this time, there is a case where the intermediate film 45 is consumed and disappears during etching of the insulating layer 43. If the sacrificial film 47 is made of a material different from that of the insulating layer 43, the sacrificial film 47 is prevented from being etched even if the intermediate film 45 disappears during etching of the insulating layer 43.

As shown in FIG. 12A, the plurality of second mask holes 44b and the plurality of first mask holes 44a (the columnar sacrificial films 47) are periodically arranged in a hexagonal close-packed pattern, for example.

The columnar sacrificial films 47 are disposed in the region on the first region R1, and the second mask holes 44b are disposed in the region on the second region R2. A film is not buried in the second mask holes 44b.

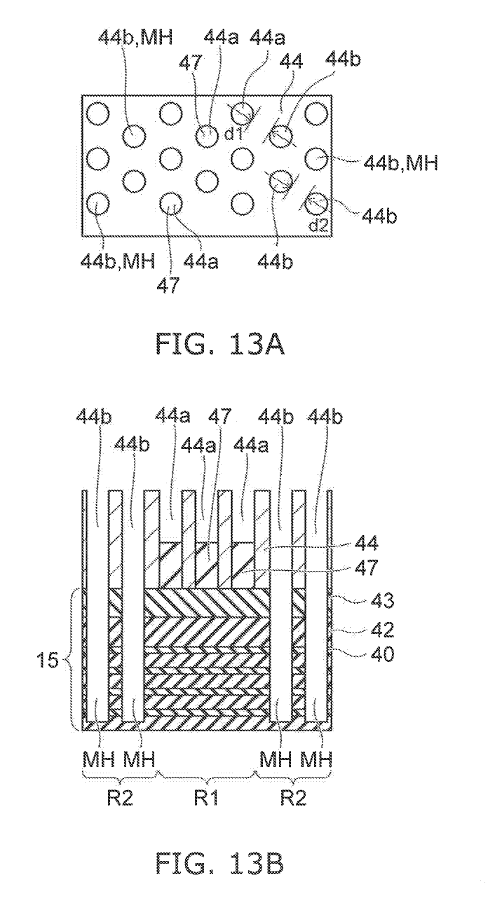

The etching target layer 15 located under the second mask holes 44b is etched according to an RIE method using the mask layer 44 in which the second mask holes 44b and the sacrificial films 47 are formed as a mask. And, as shown in FIG. 13B, the memory holes MH are formed in the etching target layer 15 under the second mask holes 44b. The memory holes MH are formed in the second region R2.

The sacrificial layers 42 and the insulating layers 40 of the second region R2 are continuously etched in a non-selective manner by using the same etching gas (for example, a gas containing fluorocarbon or hydrofluorocarbon).

During the RIE, the mask layer 44 is also consumed in the thickness direction and becomes thinned. An etching rate of the mask layer 44 is sufficiently lower than an etching rate of the etching target layer 15 (the sacrificial layers 42 and the insulating layers 40) made of a different material.

The sacrificial films 47 having an etching resistance lower than that of the mask layer 44 retreat in the depth direction of the first mask holes 44a, at an etching rate (second rate) higher than an etching rate (first rate) of the mask layer 44. The sacrificial films 47 have an etching resistance higher (an etching rate lower) than that of the sacrificial layers 42 and the insulating layers 40.

As shown in FIG. 13A, a plurality of columnar sacrificial films 47 are periodically arranged in a highly symmetrical pattern. For this reason, the plurality of columnar sacrificial films 47 are uniformly consumed, and thus retreat in the depth direction through the first mask holes 44a at an approximately equal rate.

Since the sacrificial films 47 retreat, portions (portions of upper sides including opening ends) of the first mask holes 44a are exposed onto the sacrificial films 47. With the advance of the retreat of the sacrificial films 47, the exposed parts of the first mask holes 44a are deepened. Since the plurality of sacrificial films 47 uniformly retreat, the plurality of first mask holes 44a are also uniformly deepened.

Therefore, etching of the etching target layer 15 progresses in a state in which the plurality of second mask holes 44b and the plurality of first mask holes 44a are formed in the mask layer 44. The plurality of second mask holes 44b and the plurality of first mask holes 44a are periodically arranged in a highly symmetrical pattern.

During the etching of the etching target layer 15, the first mask holes 44a and the second mask holes 44b are exposed in the mask layer 44, and the first mask holes 44a and the second mask holes 44b are periodically arranged. As shown in FIG. 13A, a distance d1 between the first mask hole 44a and the second mask hole 44b is substantially the same as a distance d2 between the second mask holes 44b.

Therefore, the mask layer 44 of the region on the first region R1 and the mask layer 44 of the region on the second region R2 are uniformly consumed and retreat.

For this reason, it is possible to minimize the asymmetric erosion of the mask layer 44 as shown in FIG. 29, and, as a result, it is possible to prevent side etching of the memory holes MH caused by the recoiled ions. Therefore, etching can be made to progress in a substantially perpendicular to the major surface of the substrate 10. As a result, it is possible to easily form the memory holes MH having straight sidewalls in which a diameter variation is minimized in the depth direction. The memory holes MH having an appropriate shape can minimize, for example, a variation in memory cell characteristics in the stacking direction.

Various conditions are set so that etching of the etching target layer 15 is completed before the sacrificial films 47 in the first mask holes 44a are removed. During etching for forming the memory holes MH in the second region R2, the first region R1 of the etching target layer 15 is protected by the sacrificial films 47 and thus is not etched. The first mask holes 44a of the mask layer 44 are not transferred to the first region R1 of the etching target layer 15. The memory holes MH are formed only in the second region R2.

The sacrificial films 47 may be caused to retreat before starting etching of the etching target layer 15, so that portions of the first mask holes 44a are exposed onto the sacrificial films 47. Etching for forming the memory holes MH is preferably completed before the sacrificial films 47 are removed.

According to the embodiment, it is possible to form the memory holes MH only in the second region R2 of the etching target layer 15 while minimizing asymmetric erosion of the mask layer 44 by using the mask layer 44 having the mask holes 44a and 44b which are distributed in a highly symmetrical pattern over the first region R1 and the second region R2.

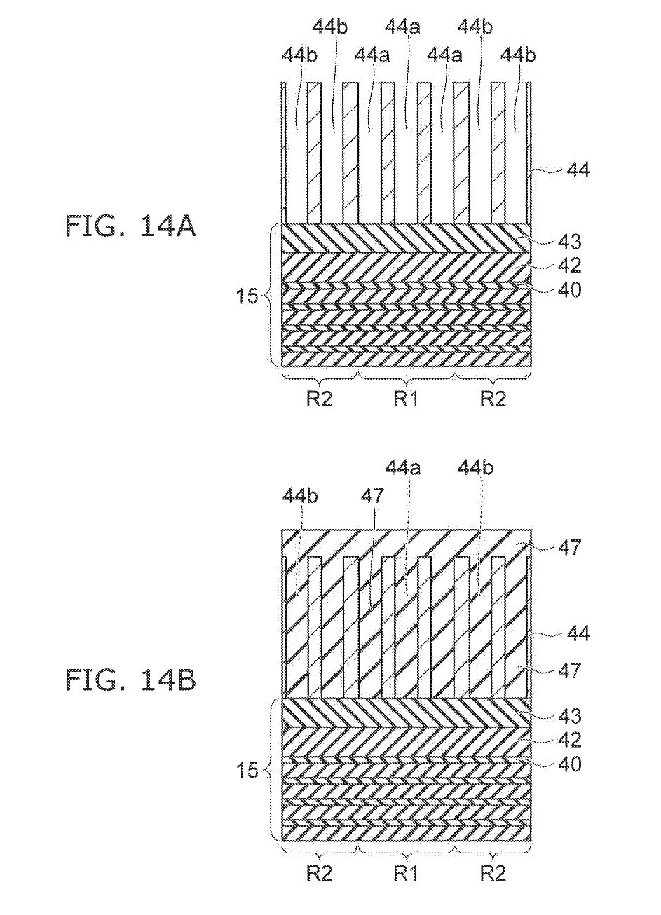

As shown in FIG. 14A, a plurality of first mask holes 44a and a plurality of second mask holes 44h may be formed simultaneously.

The mask layer 44 is formed on the etching target layer 15, and then the intermediate film 45 and the resist film 46 are formed on the mask layer 44. In addition, the first openings 46a and the second openings 46b are formed simultaneously in the resist film 46. The intermediate film 45 is processed by using the resist film 46 as a mask, and the mask layer 44 is further processed by using the intermediate film 45 as a mask, so that the first mask holes 44a and the second mask holes 44b are formed simultaneously.

A latent image pattern corresponding to the first openings 46a and a latent image pattern corresponding to the second openings 46b are transferred onto the resist film 46 through exposure. Since the latent image pattern corresponding to the first openings 46a and the latent image pattern corresponding to the second openings 46b which are periodically arranged in a highly symmetrical pattern are transferred through exposure simultaneously, it is possible to prevent the latent image patterns from being deformed.

After the first mask holes 44a and the second mask holes 44b are formed, as shown in FIG. 14B, the sacrificial film 47 is buried in the first mask holes 44a and the second mask holes 44b.

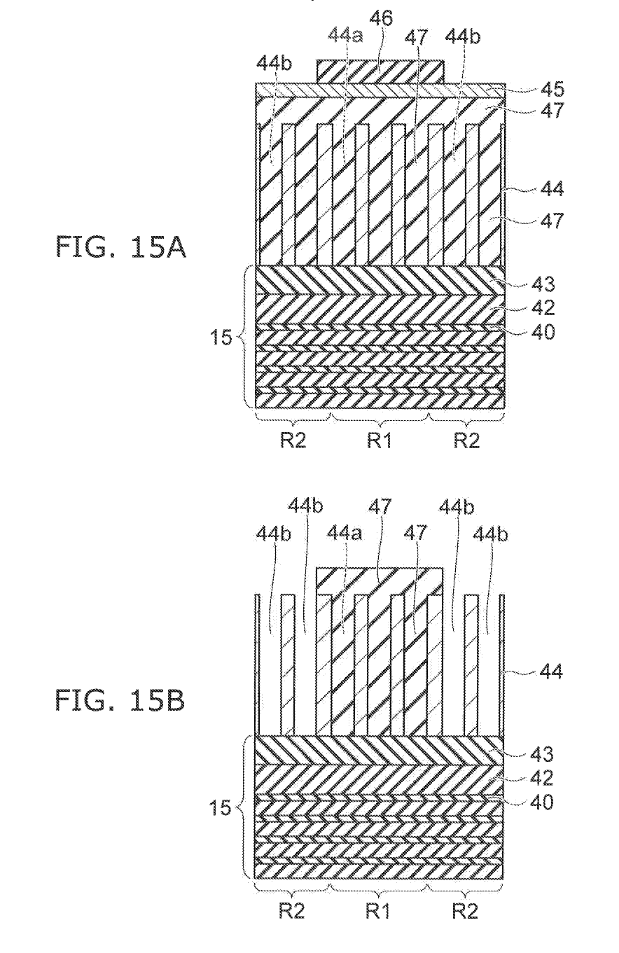

As shown in FIG. 15A, the intermediate film 45 is formed on an upper surface of the sacrificial film 47, and the resist film 46 is formed on the intermediate film 45. The resist film 46 of the region on the second region R2 is removed, and the resist film 46 of the region on the first region R1 is left, by lithography to the resist film 46.

The intermediate film 45 is processed by using the resist film 46 remaining in the region on the first region R1 as a mask, and the sacrificial film 47 in the second mask holes 44b is removed by using the intermediate film 45 remaining the region on the first region R1 as a mask. As shown in FIG. 15B, the second mask holes 44b are exposed. The sacrificial film 47 in the first mask holes 44a is left. Then, the processes subsequent to FIG. 12B are performed, and the memory holes MH are formed in the etching target layer 15.

Next, a description will be made of processes after forming the memory holes MH with reference to FIGS. 16 to 28.

As shown in FIG. 16, the memory holes MH penetrate through the etching target layer 15 and reach the substrate 10.

As shown in FIG. 17, the memory film 30 is formed on inner walls (sidewalls and bottoms) of the memory holes MH, and a cover film 20a is formed inside the memory film 30.

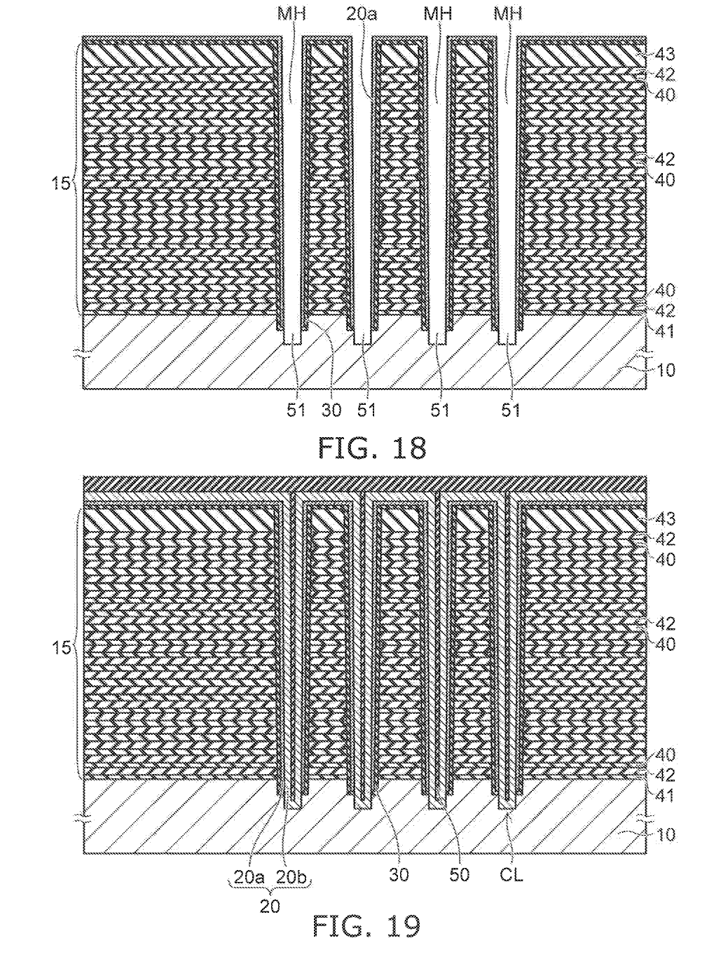

The cover film 20a and the memory film 30 formed on the bottoms of the memory holes MH are removed according to an RIE method, and, as shown in FIG. 18, contact holes 51 are formed in the bottoms of the memory holes NH. The substrate 10 forms the side surfaces and the bottom surfaces of the contact holes 51.

During this RIE, the memory film 30 formed on the sidewalls of the memory holes MH is covered and protected by the cover film 20a. Therefore, the memory film 30 formed on the sidewalls of the memory holes MH is not damaged by the RIE.

Next, as shown in FIG. 19, a channel film 20b is formed inside the contact holes 51 and the cover film 20a. The cover film 20a and the channel film 20b are formed as, for example, an amorphous silicon film, and then become a polycrystalline silicon film through an annealing process. The cover film 20a and the channel film 20b constitute the channel body 20.

The channel bodies 20 are electrically connected to the substrate 10 via the channel film 20b formed inside the contact holes 51.

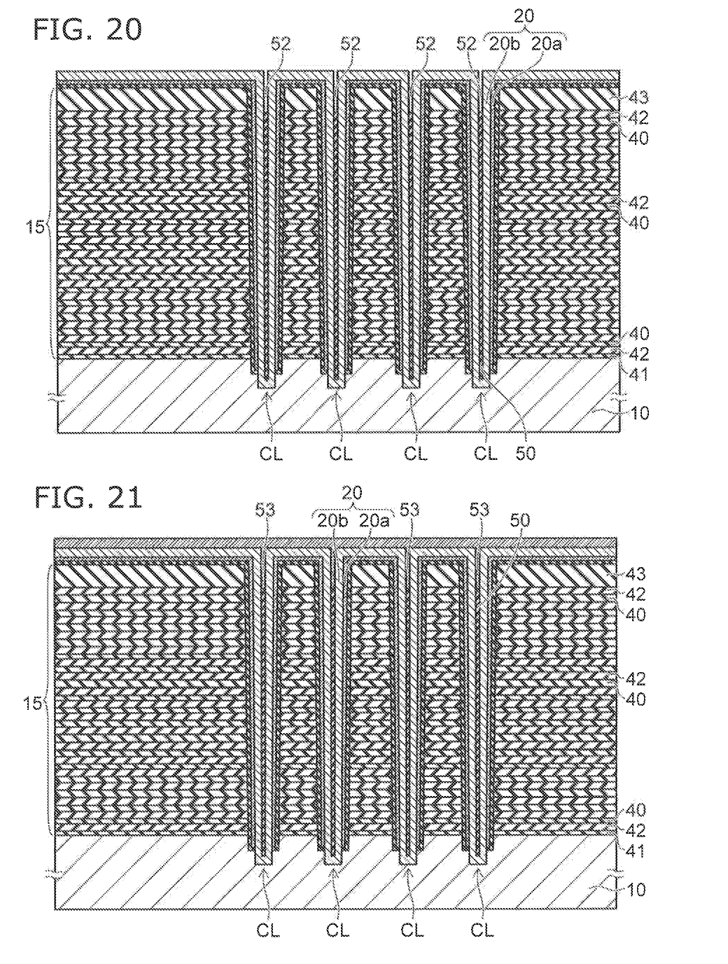

The core insulating film 50 is formed inside the channel film 20b, and thus the columnar parts CL are formed. An upper part of the core insulating film 50 is etched back, and, as shown in FIG. 20, cavities 52 are formed in the upper parts of the columnar parts CL.

As shown in FIG. 21, semiconductor films 53 are buried in the cavities 52. The semiconductor films 53 are, for example, doped silicon films, and have an impurity concentration higher than that of the channel bodies 20 which are non-doped silicon films.

In a general memory with a two-dimensional structure, electrons programmed in a floating gate are extracted by increasing a substrate potential. However, in the semiconductor memory device with a three-dimensional structure as in the embodiment, the channel of the memory cell is not directly connected to the substrate. For this reason, a channel potential of the memory cell is boosted by using a gate induced drain leakage (GIRL) current which is generated in a channel at the upper end of the drain side select gates SGD.

Holes are generated by applying a high electric field to the semiconductor films 53 formed around the upper end of the drain side select gates SGD and having the high impurity concentration. The holes are supplied to the channel body 20, thereby increasing a channel potential. When a potential of the electrode layer WL is set to, for example, a ground potential (0 V), electrons of the charge storage film 32 are extracted or holes are injected into the charge storage film 32 by a difference between the channel body 20 and the electrode layer WL, and thus a data erasure operation is performed.

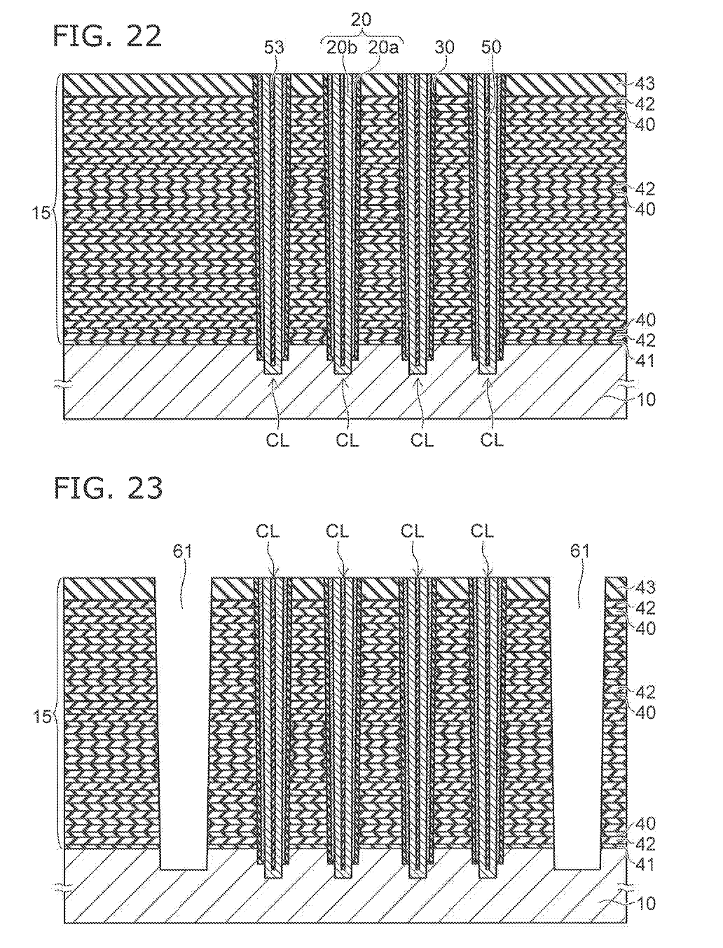

After the semiconductor films 53 are buried in the cavities 52, the memory film 30, the channel bodies 20, and the semiconductor films 53 deposited on the upper surface (the upper surface of the insulating layer 43) of the etching target layer 15 are removed (FIG. 22).

Next, as shown in FIG. 23, slits 61 are formed in the etching target layer 15 by using an RIE method using a mask (not shown). The slits 61 penetrate through the etching target layer 15 and reach the substrate 10. The slits 61 are formed in a region corresponding to the first region R1.

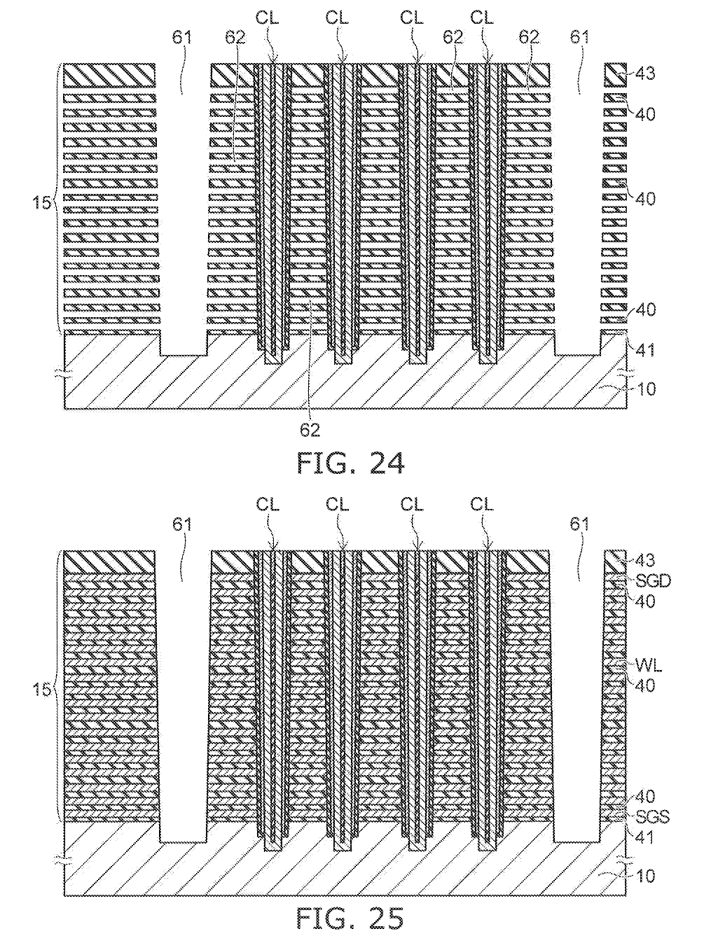

The sacrificial layers 42 are removed by etching through the slits 61. As a result of removing the sacrificial layers 42, as shown in FIG. 24, spaces 62 are formed between the insulating layer 40 and the insulating layer 40. The spaces 62 are also formed between the uppermost insulating layer 40 and the insulating layer 43, and the lowermost insulating layer 40 and the insulating layer 41.

As shown in FIG. 25, the electrode layers WL, the drain side select gates SGD, and the source side select gates SGS are formed in the spaces 62 via the slits 61. The electrode layers WL, the drain side select gates SGD, and the source side select gates SGS are metal layers, and are, for example, tungsten layers.

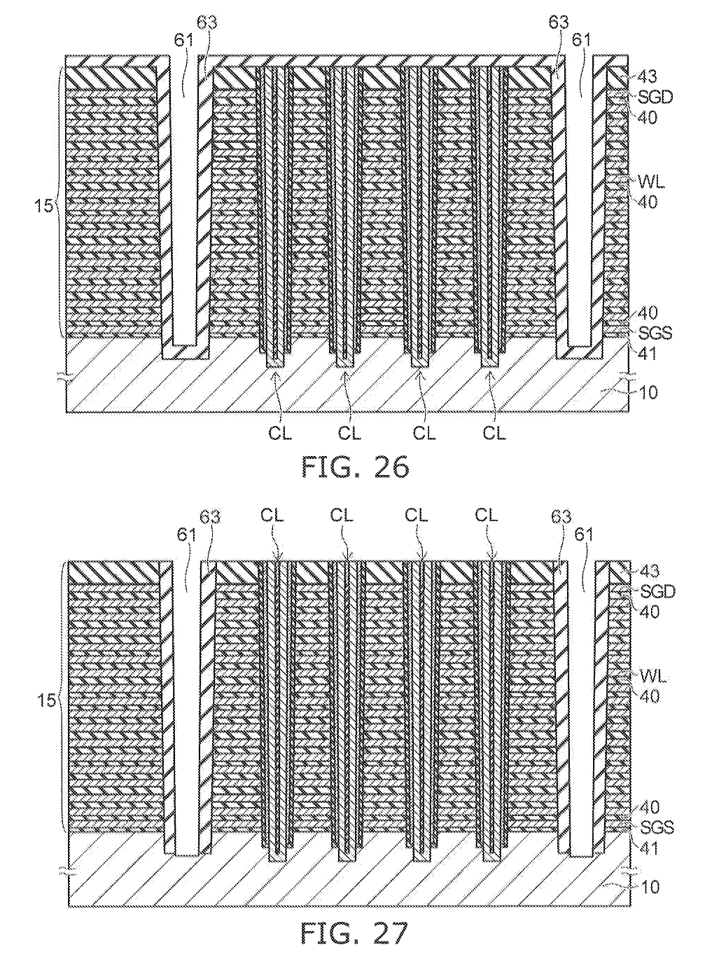

Next, as shown in FIG. 26, an insulating film 63 is formed on inner walk (sidewalls and bottoms) of the slits 61. The insulating film 63 formed on the bottoms of the slits 61 is removed by an RIE method as shown in FIG. 27.

Then, the source layers SL are buried in the slits 61 as shown in FIG. 28. Lower ends of the source layers SL are connected to the substrate 10. The lower ends of the channel bodies 20 and the source layers SL are electrically connected to each other via the substrate 10.

Subsequently, the drain side select gates SGD are isolated from each other in the Y-direction as shown in FIG. 1. Then, the bit lines BL, upper-layer interconnection connected to the source layers SL, and the like shown in FIG. 1 are formed.

In the above-described embodiment, as shown in FIG. 13A, the plurality of second mask holes 44b are periodically arranged as a mask pattern for forming the memory holes MH. The distances d2 between the plurality of respective second mask holes 44b which are periodically arranged are substantially the same as each other.

If the first mask holes 44a are not formed, a region in which distances between the holes are asymmetric is generated around the pattern end of the second mask holes 44b periodically arranged. This causes asymmetric erosion to occur in the mask layer 44 around the second mask holes 44b located at the end.

Therefore, according to the embodiment, the plurality of first mask holes 44a are also periodically arranged in the region where the memory holes MH are not formed, in the substantially same period as that of the second mask holes 44b. The distances d1 between the second mask holes 44b and the first mask holes 44a located at the end are substantially the same as the distances d2 between the second mask holes 44b.

Thus, distances between the holes, in the entire region where the plurality of second mask holes 44b including the second mask holes 44b located at the end are disposed, can be made uniform. This minimizes asymmetric erosion of the mask layer 44 of the region where the memory holes MH are formed, and facilitates control on shapes of the memory holes MH formed under the second mask holes 44b.

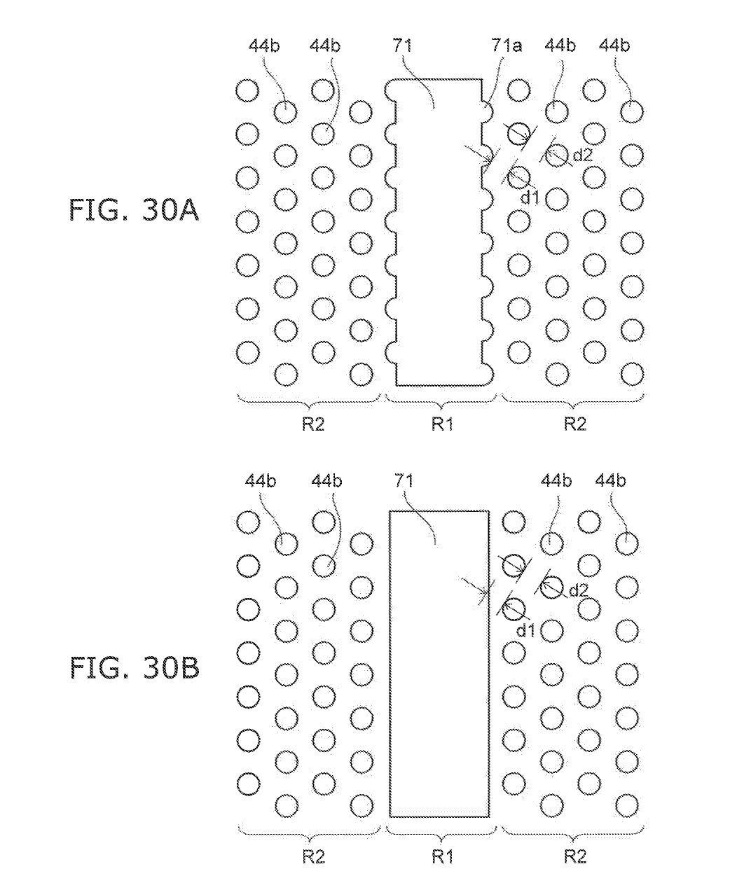

From this viewpoint, a mask pattern shown in FIG. 30A can also minimize asymmetric erosion of the mask layer 44 of the region R2 where the memory holes MH are formed.

When distances between the holes around the second mask holes 44b located at the end are made uniform, distances between the holes in the entire region where the plurality of second mask holes 44b are disposed can be made uniform, and thus it is possible to minimize asymmetric erosion of the mask layer 44.

In the pattern example shown in FIG. 30A, not holes but a space (mask space) 71 is formed in the first region R1 where the memory holes MH are not formed.

Portions 71a of holes having substantially the same diameters as those of the second mask holes 44b are formed at the ends of the mask space 71 on the second region R2 side so as to protrude the second region R2. The distance d1 between the portion 71a of the hole and the second mask hole 44b located at the end of the second region R2 is substantially the same as the distance d2 between the second mask holes 44b.

Therefore, distances between the holes in the entire region where the plurality of second mask holes 44b are disposed can be made uniform, and thus it is possible to minimize asymmetric erosion of the mask layer 44.

Similarly, a mask pattern shown in FIG. 30B can also minimize asymmetric erosion of the mask layer 44 of the second region R2 where the memory holes MH are formed.

In the pattern example shown in FIG. 30B, not holes but a space (mask space) 71 is formed in the first region R1 where the memory holes MH are not formed. A difference from the pattern shown in FIG. 30A is that portions of the holes are not formed at the ends of the mask space 71 on the second region R2 side. The ends of the mask space 71 on the second region R2 are formed linearly.

Also in this case, the distance d1 between the end of the mask space 71 and the second mask hole 44b located at the end of the second region R2 is substantially the same as the distance d2 between the second mask holes 44b. Therefore, distances between the holes in the entire region where the plurality of second mask holes 44b are disposed can be made uniform, and thus it is possible to minimize asymmetric erosion of the mask layer 44.

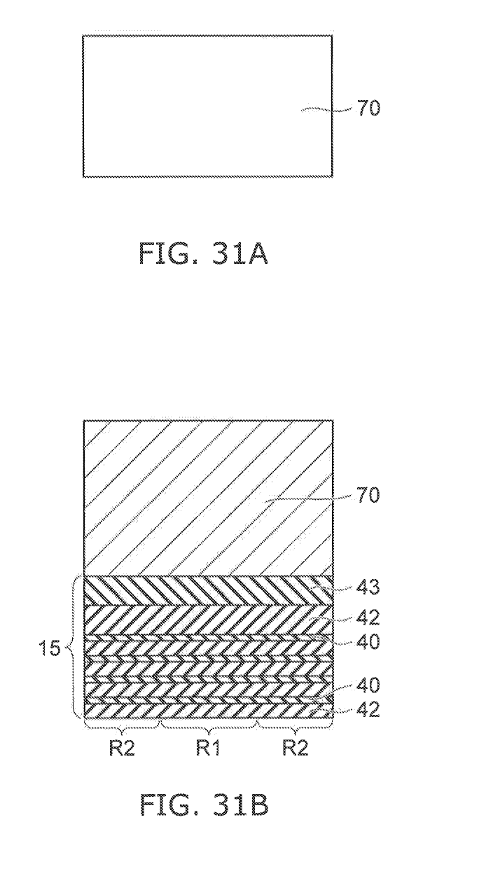

FIGS. 31A to 36B are schematic diagrams showing a method for forming the memory holes MH by using, for example, the mask pattern shown in FIG. 306.

FIGS. 31B, 32B, 33B, 34B, 35B and 36B show cross-sectional views.

FIGS. 31A, 32A, 33A, 34A, 35A and 36A respectively correspond to top views of FIGS. 31B, 32B, 336, 34B, 35B and 36B.

In the same manner as in the embodiment described with reference to FIG. 3, an etching target layer (stacked body) 15 having a plurality of sacrificial layers (first layers) 42 and a plurality of insulating layers (second layers) 40 is formed on the substrate 10. As shown in FIG. 31B, a mask layer 70 is formed on the etching target layer 15. The mask layer 70 is an amorphous silicon film which is formed by using, for example, a CVD method. The mask layer 70 may be a tungsten film which is formed by using, for example, a sputtering method.

In the same manner as in the above-described embodiment, a resist film is formed on the mask layer 70 via, for example, an intermediate film, and the resist film is patterned through lithography on the resist film. The pattern of the resist film is transferred onto the mask layer 70.

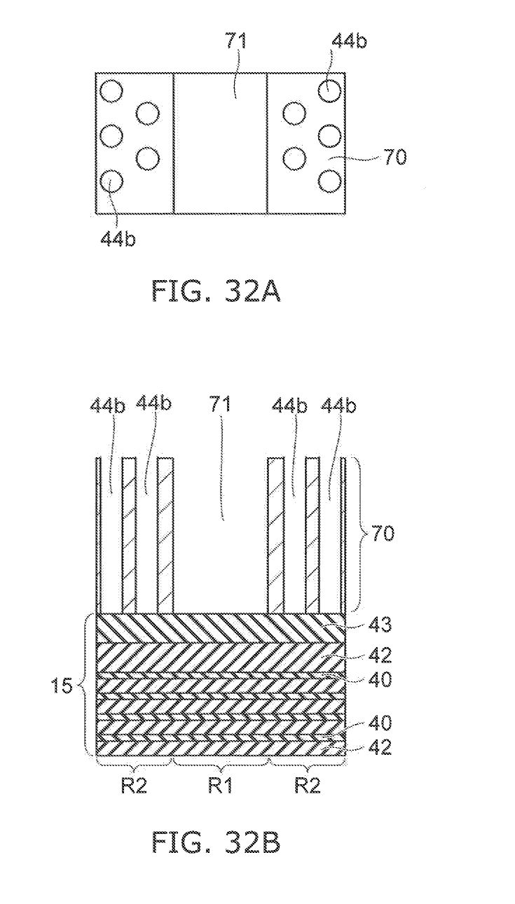

In other words, as shown in FIGS. 32A and 32B, a mask space 71 and a plurality of mask holes 44b are formed in the mask layer 70 according to an RIE method of using the resist film 46 and the intermediate film 45 as a mask.

The mask holes 44b and the mask space 71 penetrate through the mask layer 70, and reach the uppermost layer (the insulating layer 43) of the etching target layer 15.

The mask holes 44b are formed in a region on the second region R2 where the memory holes MH are to be formed. The plurality of mask holes 44b have a periodic arrangement (for example, hexagonal close-packed arrangement) in the region on the second region R2.

The mask space 71 is formed in a region on the first region R1 where the memory holes MH are not formed. In the top view of FIG. 32A, sidewalls of the mask space 71 on the second region R2 side extend linearly.

Alternatively, the mask space 71 having the portions 71a of holes shown in FIG. 30A on the sidewalls thereof may be formed in the mask layer 70 by patterning the resist film having corresponding portions of holes.

A width (a width between both wall surfaces on the second region R2 side) of the mask space 71 is larger than the diameter of the mask hole 44b.

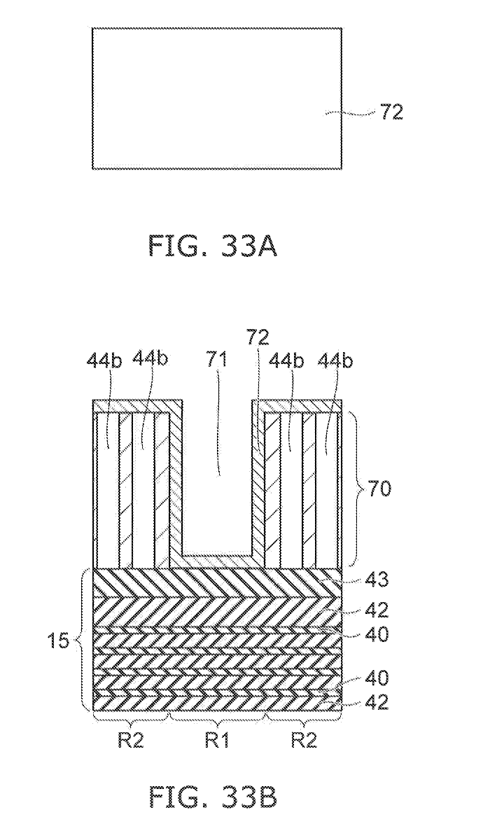

A first sacrificial film 72 is formed inside the mask space 71 as shown in FIG. 33B. The first sacrificial film 72 is made of a material different from that of the mask layer 70. In addition, the first sacrificial film 72 has an etching resistance lower than that of the mask layer 70 relative to an etching condition of the etching target layer 15. In other words, when the etching target layer 15 is etched, an etching rate (second rate) of the first sacrificial film 72 is higher than an etching rate (first rate) of the mask layer 70.

As the first sacrificial film 72, for example, a carbon film is formed by using a CVD method. The first sacrificial film 72 is conformally formed along the upper surface of the mask layer 70, and the sidewalls and the bottom of the mask space 71.

The first sacrificial film 72 does not enter into the mask holes 44b having the diameter smaller than the width of the mask space 71. The first sacrificial film 72 is not buried in the mask holes 44b but closes the openings of the mask holes 44b.

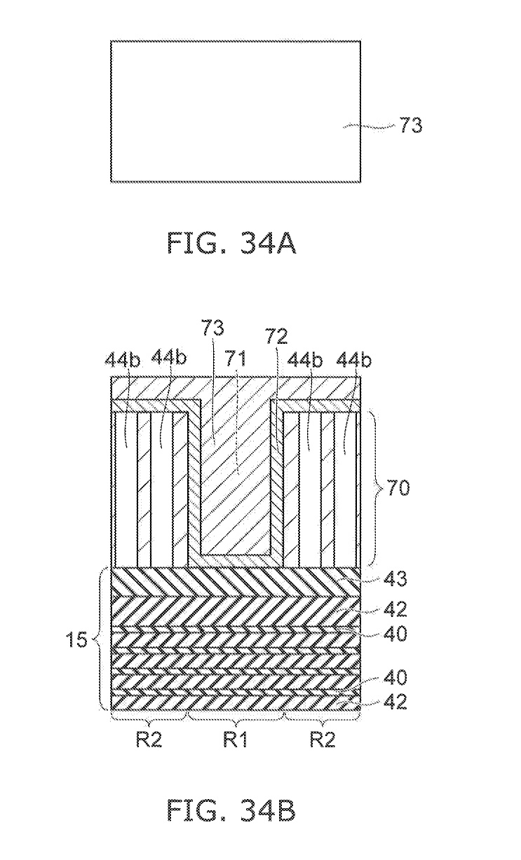

A cavity remains inside the first sacrificial film 72 in the mask space 71. A second sacrificial film 73 is buried in the cavity as shown in FIG. 34B. The second sacrificial film 73 is also formed on the first sacrificial film 72 located on the upper surface of the mask layer 70.

The second sacrificial film 73 is made of a material different from that of the mask layer 70. In addition, the second sacrificial film 73 has an etching resistance lower than that of the mask layer 70 relative to an etching condition of the etching target layer 15. In other words, when the etching target layer 15 is etched, an etching rate (second rate) of the second sacrificial film 73 is higher than an etching rate (first rate) of the mask layer 70. As the second sacrificial film 73, for example, an organic film is formed by using a coating method.

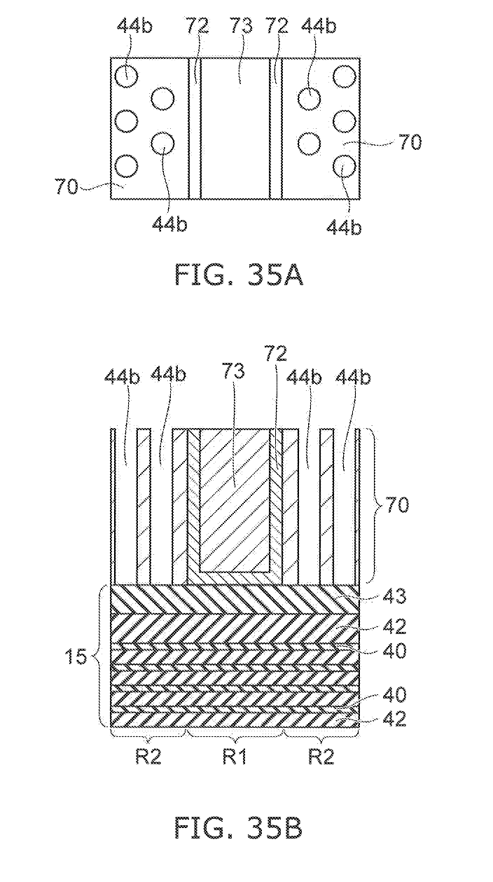

Next, the upper surface of the second sacrificial film 73 is etched back, and then the first sacrificial film 72 on the mask layer 70 is etched back. The first sacrificial film 72 which closes the openings of the mask holes 44b is removed, and thus the mask holes 44b are exposed as shown in FIG. 35B.

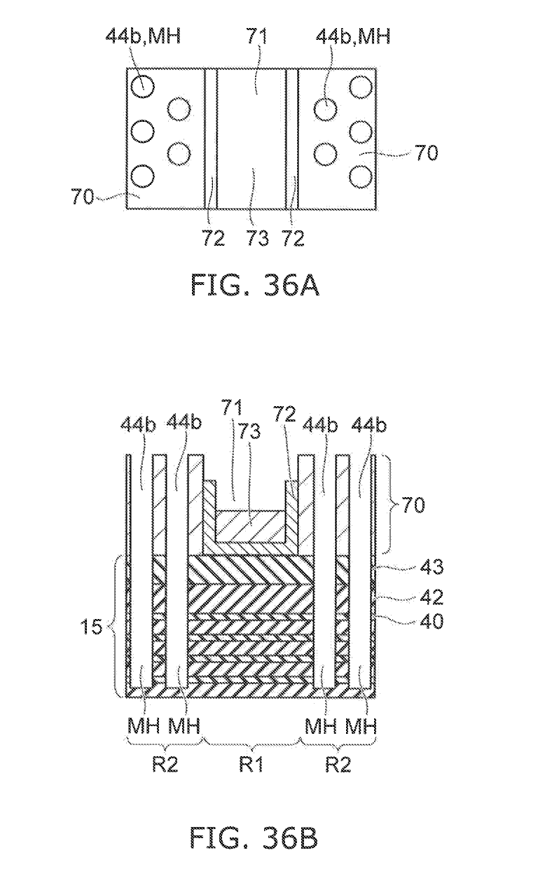

The first sacrificial film 72 and the second sacrificial film 73 are buried in the mask space 71. Then, the etching target layer 15 is etched according to an RIE method of using the mask layer 70, the first sacrificial film 72, and the second sacrificial film 73 as a mask, and the memory holes MH are formed under the mask holes 44b as shown in FIG. 36B. Before starting the etching of the etching target layer 15, the first sacrificial film 72 and the second sacrificial film 73 may be made to retreat in the depth direction of the mask space 71 so that a portion of the mask space 71 may be exposed.

The sacrificial layers 42 and the insulating layers 40 of the second region R2 are continuously etched in a non-selective manner by using the same etching gas (for example, a gas containing fluorocarbon or hydrofluorocarbon).

During the RIE, the mask layer 70 is also consumed in the thickness direction and becomes thinned. An etching rate of the mask layer 70 is sufficiently lower than an etching rate of the etching target layer 15 (the sacrificial layers 42 and the insulating layers 40).

The first sacrificial film 72 and the second sacrificial film 73 having an etching resistance lower than that of the mask layer 70 retreat in the depth direction of the mask space 71, at an etching rate (second rate) higher than an etching rate (first rate) of the mask layer 70. The first sacrificial film 72 and the second sacrificial film 73 have an etching resistance higher (an etching rate lower) than that of the sacrificial layers 42 and the insulating layers 40 of the etching target layer 15.

Due to the retreat of the first sacrificial film 72 and the second sacrificial film 73, a portion (a portion of the upper side including an opening end) of the mask space 71 is exposed onto the first sacrificial film 72 and the second sacrificial film 73. With the advance of the retreat of the first sacrificial film 72 and the second sacrificial film 73, the exposed part of the mask space 71 is deepened.

Therefore, as shown in FIG. 30B, the etching of the etching target layer 15 progresses in a state in which the distance d1 between the end of the mask space 71 and the second mask hole 44b located at the end of the region on the second region R2 is substantially the same as the distance d2 between the second mask holes 44b.

For this reason, a height of the mask layer 70 of the entire region on the second region R2 where the plurality of mask holes 44b are periodically arranged can be made to uniformly retreat. For this reason, it is possible to minimize the asymmetric erosion of the mask layer 70 of the region on the second region R2, and, as a result, it is possible to prevent side etching of the memory holes MH caused by the recoiled ions.

Therefore, etching can be made to progress in a substantially perpendicular to the major surface of the substrate 10. As a result, it is possible to easily form the memory holes MH having straight sidewalls in which a diameter variation is minimized in the depth direction. The memory holes MH having an appropriate shape can minimize, for example, a variation in memory cell characteristics in the stacking direction.

Various conditions are set so that etching of the etching target layer 15 is completed before the first sacrificial film 72 and the second sacrificial film 73 in the mask space 71 are removed. During etching for forming the memory holes MH in the second region R2, the first region R1 of the etching target layer 15 is protected by the first sacrificial film 72 and the second sacrificial film 73 and thus is not etched. The mask space 71 is not transferred to the first region R1 of the etching target layer 15.

The etching target layer 15 is not limited to a stacked film in which different kinds of films are alternately repeatedly stacked, and may be a stacked film having no repetitive structure, or a single-layer film of the same kind. The above-described embodiment is suitable for forming holes with a high aspect ratio regardless of a material or a structure of the etching target layer 15.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device comprising:
forming a mask layer made of a material different from a material of an etching target layer above the etching target layer;
forming a plurality of first mask holes, a plurality of sacrificial films, and a plurality of second mask holes in the mask layer, the sacrificial films being buried in the first mask holes and made of a material different from a material of the mask layer;
retreating the sacrificial films in a depth direction of the first mask holes to expose portions of the first mask holes onto the sacrificial films; and
etching the etching target layer under the second mask holes using the mask layer and the sacrificial films as a mask, to form holes in the etching target layer under the second mask holes.

2. The method according to claim 1, wherein the etching target layer under the first mask holes is protected by the sacrificial films and is not etched during the etching for forming the holes in the etching target layer.

3. The method according to claim 1, wherein the mask layer retreats at a first rate, and the sacrificial films retreat at a second rate higher than the first rate during the etching of the etching target layer.

4. The method according to claim 1, wherein
the first mask holes and the sacrificial films in the first mask holes are formed before forming the second mask holes, and the second mask holes are formed with protecting the sacrificial films.

5. The method according to claim 1, wherein
the first mask holes and the second mask holes are formed simultaneously, the sacrificial films are buried in the first mask holes and the second mask holes, and then the sacrificial films in the second mask holes are removed.

6. The method according to claim 1, wherein the first mask holes and the second mask holes are periodically arranged.

7. The method according to claim 6, wherein a distance between the first mask hole and the second mask hole is substantially equal to a distance between the second mask holes.

8. The method according to claim 1, wherein the etching target layer has a plurality of first layers and a plurality of second layers, each of the second layers being provided between the first layers.

9. The method according to claim 8, wherein the first layers which are silicon nitride films and the second layers which are silicon oxide films are continuously etched by a reactive ion etching (RIE) method using a gas containing fluorocarbon or hydrofluorocarbon.

10. The method according to claim 9, wherein the mask layer is a carbon film, and the sacrificial films are organic films or films containing silicon oxide.

11. A method for manufacturing a semiconductor device comprising:
forming a mask layer made of a material different from a material of an etching target layer above the etching target layer;
forming a plurality of mask holes, a mask space, and a sacrificial film in the mask layer, the sacrificial film being buried in the mask space and made of a material different from a material of the mask layer;
retreating the sacrificial film in a depth direction of the mask space to expose a portion of the mask space onto the sacrificial film; and
etching the etching target layer under the mask holes using the mask layer and the sacrificial film as a mask, to form holes in the etching target layer under the mask holes.

12. The method according to claim 11, wherein the etching target layer under the mask space is protected by the sacrificial film and is not etched during the etching for forming the holes in the etching target layer.

13. The method according to claim 11, wherein the mask layer retreats at a first rate, and the sacrificial film retreats at a second rate higher than the first rate during the etching of the etching target layer.

14. The method according to claim 11, wherein the forming of the sacrificial film includes
forming a first sacrificial film along a sidewall and a bottom of the mask space and closing openings of the mask holes with the first sacrificial film;
forming a second sacrificial film on the first sacrificial film on the mask layer, and inside the first sacrificial film in the mask space; and
etching back the second sacrificial film and the first sacrificial film on the mask layer to expose the mask holes.

15. The method according to claim 14, wherein a width of the mask space is larger than a diameter of the mask hole.

16. The method according to claim 11, wherein the mask holes are periodically arranged.

17. The method according to claim 16, wherein a distance between the mask hole and the mask space is substantially equal to a distance between the mask holes.

18. The method according to claim 14, wherein the etching target layer has a plurality of first layers and a plurality of second layers, each of the second layers being provided between the first layers.

19. The method according to claim 18, wherein the first layers which are silicon nitride films and the second layers which are silicon oxide films are continuously etched by a reactive ion etching (RIE) method using a gas containing fluorocarbon or hydrofluorocarbon.

20. The method according to claim 19, wherein the mask layer is a silicon film, the first sacrificial film is a carbon film, and the second sacrificial film is an organic film.
